(19) United States
(12) Patent Application Publication
(10) Pub. No.: US 2012/0129441 A1
(43) Pub. Date: May 24, 2012

(54) COMPUTER SERVER CENTER

(75) Inventors: WEN-TANG PENG, Tu-Cheng (TW); YI-LIANG HSIAO, Tu-Cheng (TW)

(73) Assignee: HON HAI PRECISION INDUSTRY CO., LTD., Tu-Cheng (TW)

(21) Appl. No.: 12/975,283

(22) Filed: Dec. 21, 2010

(30) Foreign Application Priority Data
Nov. 22, 2010 (TW) 99140263

(51) Int. Cl. H05K 5/02

(52) U.S. Cl. 454/184

(57) ABSTRACT

A computer server center includes a pair of server racks, a pair of separating boards, and a condenser. The pair of server racks are arranged to face each other. The pair of separating boards connect two sides of the pair of server racks to define a separating room between the pair of server racks. The condenser is received in the separating room, configured for generating cool air, and individually adjustable to control the flux of the cool air.

### BACKGROUND

1. Technical Field

The present disclosure relates to computer server centers and, particularly, to a computer server center with satisfactory heat dissipation.

2. Description of Related Art

Computer server centers often include a number of server racks. Each server rack may contain different numbers and/or kinds of computer server modules and therefore require different fluxes of cooling air for efficient heat dissipation of the computer server modules. However, current computer server centers cannot proportionally allocate cooling air to the server racks as needed. As a result, the computer server modules in some server racks cannot receive sufficient cooling air.

Therefore, it is desirable to provide a computer server center, which can overcome the limitations described.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic view of a computer server center, according to an embodiment.

FIG. 2 is a schematic view of a computer server center, according to another embodiment.

### DETAILED DESCRIPTION

Embodiments of the present disclosure will now be described in detail with reference to the drawings.

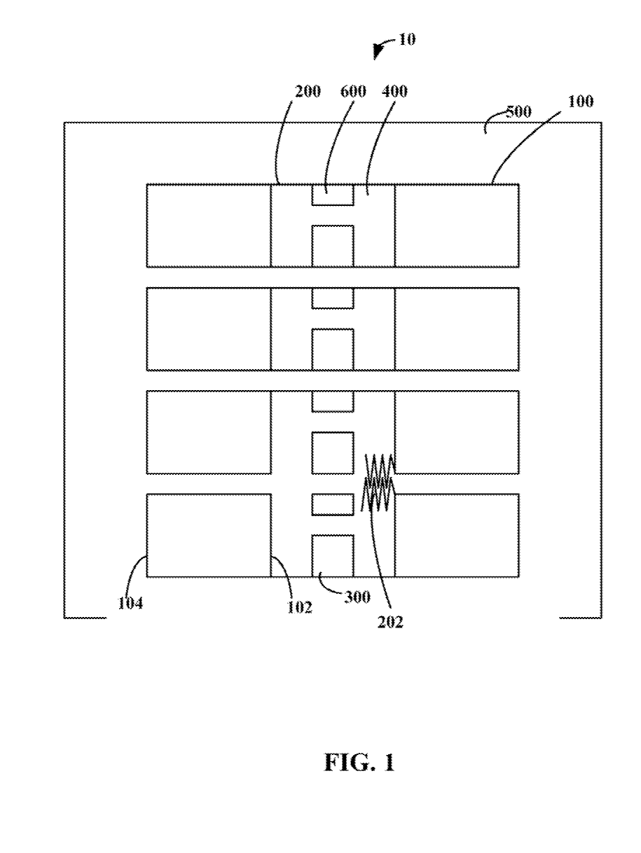

Referring to FIG. 1, a computer server center 10, according to an embodiment, includes four pairs of server racks 100, four pairs of separating boards 200, and four condensers 300. Each pair of server racks 100 are arranged to face each other. Each pair of separating boards 200 connecting two sides of a corresponding pair of server racks 100 to form a separating room 400 between the corresponding pair of server racks 100. Each condenser 40 is received within the corresponding separating room 400, configured for generating cooling air for the corresponding pair of server racks 100, and is individually adjustable to control the flux of the cooling air.

Thus, each pair of server racks 100 can receive a suitable and sufficient flux of cooling air for efficient heat dissipation of computer server modules (not shown) received in the server racks 100 by individually adjusting the corresponding condenser 300.

In particular, the computer server center 10 forms a receiving room 500. The server racks 100, the separating boards 200, and the condensers 300 are received in the receiving room 500. Each server rack 100 defines an inlet 102 and an outlet 104 opposite to and communicating with the inlet 102. The computer server modules are mounted in the corresponding server rack 100 between the corresponding inlet 102 and outlet 104. The inlets 102 directly communicate with the respective separating rooms 400. Thus, cooling air generated by the condensers 300 can directly flow into the respective inlets 102, flow through the respective server racks 100, and flow out from the respective outlets 104 dissipating heat generated by the respective computer server modules. In this embodiment, the four pairs of server racks 100 are arranged in two rows. However, the number and the arrangement of the server racks 100 are not limited to this embodiment but can be set according to need. For example, the computer server center 10 may have only one pair of server racks 100.

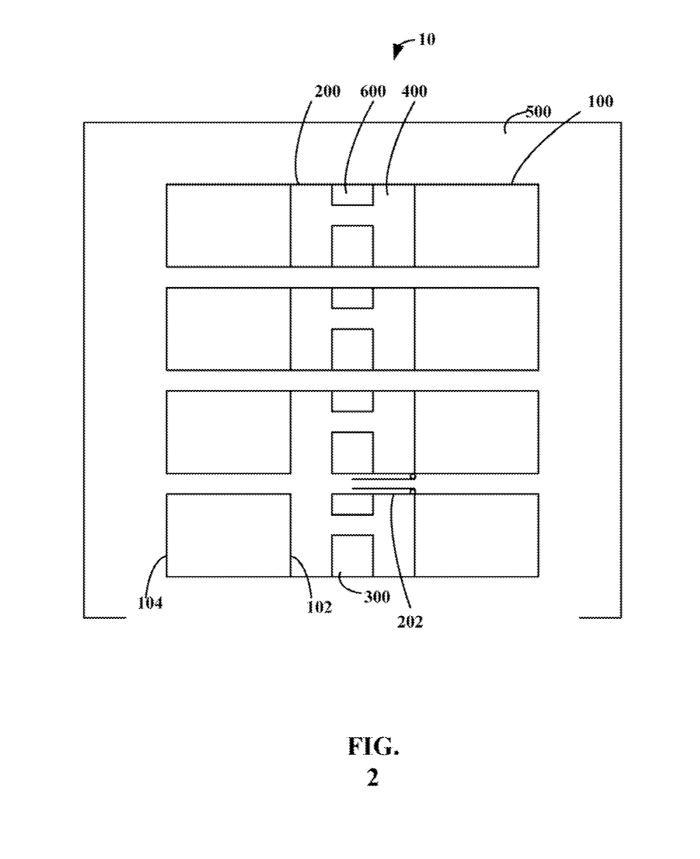

Each separating board 200 can include a door 202. Thus, when the pair of server racks 100 does not require an individually adjustable flux of cooling air, the door 202 can be opened to the corresponding separating room 400. In this embodiment, the door 202 is a folding door. However, the door 202 is not limited to this embodiment. Referring to FIG. 2, in another embodiment, the door 202 can be a sliding door.

Each condenser 300 is suspended from the ceiling within the corresponding separating room 400. The computer server center 10 can include four temperature sensors 600. Each temperature sensor 600 is received in the corresponding separating room 400 to sense the ambient temperature in the corresponding separating room 400. Thus, the condensers 300 can be individually adjusted according to the sensed temperature of the respective temperature sensors 600.

It will be understood that the above particular embodiments are shown and described by way of illustration only. The principles and the features of the present disclosure may be employed in various and numerous embodiment thereof without departing from the scope of the disclosure as claimed. The above-described embodiments illustrate the scope of the disclosure but do not restrict the scope of the disclosure.

What is claimed is:

1. A computer server center, comprising:
a pair of server racks facing each other;
a pair of separating board connecting two sides of the pair of server racks to define a separating room between the pair of server racks; and
a condenser received in the separating room, configured for generating cool air, and individually adjustable to control the flux of the cool air.

2. The computer server center of claim 1, defining a receiving room, wherein the server racks, the separating boards, and the condenser are received in the receiving room.

3. The computer server center of claim 1, wherein each server rack comprises an inlet and an outlet opposite to and communicating with the inlet, and the inlet directly communicates with the separating room.

4. The computer server center of claim 1, wherein each separating board comprises a door.

5. The computer server center of claim 4, wherein the door is selected from the group consisting of a fold door and a sliding door.

6. The computer server center of claim 1, comprising a temperature sensor received in the separating room and configured for sensing the temperature of the separating room.
